(19) United States
(12) Patent Application Publication
(10) Pub. No.: US 2015/0325711 A1
(43) Pub. Date: Nov. 12, 2015

(54) SEMICONDUCTOR COMPONENT HAVING HARDNESS BUFFER AND USE THEREOF

(71) Applicant: Fraunhofer-Gesellschaft Zur Forderung Der Angewandten Forschung E. V., Munchen (DE)

(72) Inventors: Frank Dimroth, Gundel Fingen (DE); Vera Klinger, Freiburg (DE)

(73) Assignee: Fraunhofer-Gesellschaft Zur Forderung Der Angewandten Forschung E.V., Munchen (DE)

(21) Appl. No.: 14/801,177

(22) Filed: Jul. 16, 2015

Related U.S. Application Data
(63) Continuation of application No. PCT/EP2014/050395, filed on Jan. 10, 2014.

(30) Foreign Application Priority Data
Jan. 18, 2013 (DE) 10 2013 000 882.4

(51) Int. Cl. H01L 31/0216; H02S 40/22; H01L 31/0725; H01L 31/054; H01L 31/0745; H01L 31/0735

(52) U.S. Cl. CPC H01L 31/02167; H01L 31/0745; H01L 31/0735; H01L 31/0725; H01L 31/054; H02S 40/22

(57) ABSTRACT

The invention relates to a semiconductor component that has an improved hardness buffer compared to the prior art. Lower penetrating dislocation densities are achieved thereby, especially for buffer layers having an increasing lattice constant. The semiconductor component according to the invention can be a solar cell. In this case a substantially higher efficiency of the solar cell is observed compared to conventional solar cells, thanks to the improved hardness buffer. The invention further relates to the use of the semiconductor component according to the invention or of the multiple solar cell according to the invention for energy generation in satellites in space or in terrestrial photovoltaic concentrator systems.

The invention relates to a semiconductor component which has an improved hardness buffer relative to the state of the art. Consequently, lower penetrating dislocation densities are achieved, above all for buffer layers with increasing lattice constant. The semiconductor component according to the invention can concern a solar cell. In this case, substantially greater efficiency of the solar cell, compared with conventional solar cells, is observed due to the improved hardness buffer. Furthermore, the use of the semiconductor component according to the invention or of the multiple solar cell according to the invention is proposed for current generation in satellites in space or in terrestrial photovoltaic concentrator systems.

The current standard for III-V multiple solar cells consists of three p-n junctions having the materials Ga_{0.5}In_{0.5}P, Ga_{0.99}In_{0.01}As and Ge which are grown one above the other adapted in lattice. It is known that the efficiency of these solar cells can be increased by better selection of the band gap energies. The optimum band gap combinations are thereby often achievable only with materials which have different lattice constants. In these cases, metamorphic buffer layers in which the atomic distances in the crystal can be changed and the lattice can be relaxed must be incorporated between the partial cells.

However, in the metamorphic buffers, dislocations are formed by the strain of the crystal lattice (Matthews & Blakeslee, 1974, Journal of Crystal Growth, 27:118-125). These should remain restricted to the buffer and not reach the active part of the solar cell with the p-n junction.

A distinction is made between two types of dislocations, so-called mismatch dislocations and penetrating dislocations.

Mismatch dislocations extend in the growth plane and end preferably at the edge of the epitaxial substrates. They lead to a reduction in the strains in the crystal. These dislocations are essential for relaxing the crystal lattice and ending at the end of the buffer structure with a cubic lattice.

Penetrating dislocations (partially also termed thread dislocations) run, in contrast, in the growth direction and end at the surface of the epitaxial substrates. The dislocations continue with the epitaxial growth and hence penetrate the active layers of the solar cell at the p-n junction. In fact multiplication of the dislocations during growth and increased roughness of the surface can hereby result.

Photogenerated minority charge carriers recombine preferably at dislocations and then no longer contribute to the photocurrent. Hence, a substantial loss mechanism which acts negatively on the solar cell efficiency is produced. The density of penetrating dislocations at the end of metamorphic buffer layers must therefore be minimised.

Mismatch dislocations are formed because of strains in the buffer layers. It should thereby be noted that such mismatch dislocations can be limited by penetrating dislocations. If the dislocation arms move to the edge of the substrates, then ultimately only a mismatch dislocation still remains in the plane which contributes to the strain relaxation and simultaneously has no effect at all upon the active regions of the solar cell. It is therefore important to assist the dislocation slipping in the buffer layers.

At the same time, it is advantageous not to produce mismatch dislocations at the surface but rather more deeply in the crystal. Thus a negative effect on the growth process at the surface can be avoided.

Mismatch dislocations are formed preferably in softer crystal layers with a lesser bond strength between the atoms. Higher mobility of the dislocations which must typically slip on the crystal planes up to the edge of the substrates also exists here. It is advantageous if mismatch dislocations in soft layers are formed below the surface and can propagate there in the growth plane up to the edge.

Current buffer structures in III-V multiple solar cells generally do not fulfil these criteria and hence result in an increased density of penetrating dislocations. It is known that an abrupt transition from a crystal lattice with a small to a large lattice constant is unfavourable and can lead to the formation of numerous penetrating dislocations.

For this reason, nowadays buffer structures with a large number of individual layers are typically used, the lattice constant being varied linearly or incrementally within the buffer. This takes place for example by a gradual increase of indium in Ga₁₋ₓInₓAs (Bett et al., 2005, Materials Research Society Symposiurn Proceedings, vol. 836, p. 223-234; Dimroth et al., 2009, Photovoltaic Specialists Conference (PVSC), 34^{th} IEEE).

Frequently investigated buffer structures consist of SiGe on Si, GaAsP on GaP, GaInAs, AlGaInAs or GaInP on GaAs or Ge. Previous buffer structures are thereby typically produced from a ternary or quaternary material system by varying the composition (e.g. In content x in Ga₁₋ₓInₓAs). The lattice constant is thereby changed incrementally and the crystal relaxes after exceeding a critical layer thickness via the formation of dislocations.

In fact, the crystal hardness of ternary and quaternary mixed crystals in a specific composition range is always above the values for the binary end points (“solid solution hardening”; see Goryunova et al., 1965, Hardness, vol. 4, p. 3-34). Hence, during the transition from a binary material to a larger or smaller lattice constant, generally a situation occurs in which the crystal hardness of the ternary or quaternary transition layer firstly increases and then decreases again.

Furthermore, it is found that the crystal hardness of the III-V compound semiconductors generally decreases with increasing lattice constant. This is connected with a reduction in the bond energy at a greater distance between the crystal atoms (Kühn et al., 1972, Kristall and Technik (Crystal and Technology), vol. 7, p. 1077-1088).

Most buffer structures in solar cells are used to effect a transition from a smaller lattice constant to a larger lattice constant. The crystal hardness thereby initially increases then however decreases after a specific composition of the buffer structures. The reduced crystal hardness at the surface leads to a preferred formation of dislocations in the softer layers at the surface and hence to increased roughness and penetrating dislocation density.

Subsequently, representatives of metamorphic buffer structures with a transition from smaller to larger lattice constants are listed. In the case of these examples, the crystal hardness of the uppermost buffer layers decreases if a specific lattice constant is exceeded:
In metamorphic triple solar cells on germanium, Ga₁₋ₓInₓAs buffer layers on germanium are used in order to convert the lattice constant from Ge to the lattice constant of Ga_{0.83}In_{0.17}As. A difference in the lattice constant of 1.1% must thereby be bridged. The crystal hardness increases continually in these buffer structures made of GaInAs. The transition is achieved nowadays, for example in eight steps of equal size. On the buffer structures, excellent multiple solar cells made of Ga_{0.35}In_{0.65}P/Ga_{0.83}In_{0.17}As/Ge with an efficiency of 41.1% could even be achieved (Dimroth et al., 2009, Photovoltaic Specialists Conference (PVSC), 34^{th} IEEE, 2009; Guter et al., 2009, Applied Physics Letters, vol. 94, p. 223504-223513). The crystal hardness for GaInAs becomes, with a lattice constant in the range of 5.8 Angstrom (Ga_{0.64}In_{0.36}As with 0.94 eV), very flat and then with increasing indium content decreases to InAs. The use of pure GaInAs buffer layers in this composition range is unfavourable.
A further material system consists of Ga₁₋ₓInₓP with x>0.5 on GaAs (S. Klinger et al., 2011, Photovoltaic Specialists Conference (PVSC), 2011, 37^{th} IEEE, 2011) which is used in particular in inverted metamorphic solar cells. Here also, the lattice constant increases with the indium content. In this case, basically the hardness of the buffer layers decreases towards the surface. This is an unfavourable situation which leads to increased penetrating dislocation densities.
A further material system consists of GaAs_{y}P_{1-y} on GaP (Hayashi et al., 1994, Proceedings of the 35t^{h} IEEE Photovoltaics Specialists Conference, Waikoloa, Hawai; Grassman et al., 2010, IEEE Transactions on Electron Devices, vol. 57, p. 3361-3369) and allows a transition in the lattice constant from gallium phosphide to gallium arsenide to be achieved. Here also the crystal hardness initially increases and then decreases sharply after a specific arsenic concentration to gallium arsenide. This is unfavourable for the above-mentioned reasons.

It is known from the state of the art that particularly hard layers of nitrogen- or boron-containing compound semiconductors can be used for the purpose of “bending” penetrating dislocations in metamorphic buffer structures into the plane. Such blocker layers made of GaInNAs are described by Schone et al. (Schone et al., 2008, Applied Physics Letters, vol. 92, p. 81905-3). The use of such blocker layers for reducing the dislocation density is known from EP 2 031 641 A1.

The blocker layers are incorporated above and below the metamorphic buffer structure. This thereby concerns functional components of a buffer structure, which are not used however for relaxation of the crystal, but exclusively for blocking or bending dislocations. The blocker layers are therefore not relaxed and are situated typically above or below the buffer structures.

Current metamorphic buffer structures have yet another component. At the end of the buffer structures, the crystal lattice should be completely relaxed, hence subsequently the solar cell structures can be grown without strain. In order to achieve this, a so-called excess layer is inserted in the structures. This layer leads to an additional strain which extends beyond the target lattice constant and leads to the buffer layers situated below being further relaxed. As soon as the lattice constant of the excess layer in the horizontal plane corresponds to the target lattice constant, the growth with the target lattice constant is continued extensively without strain.

An optimum structure of metamorphic buffer layers is constructed such that the crystal at the surface is completely strained during growth and relaxation of the crystal lattice is effected exclusively in deeper layers. The gradient in the lattice constant is correspondingly set in order to prevent relaxation of the respectively uppermost layer.

In order to minimise the dislocation formation at the surface, the crystal hardness within the buffer layers should have a tendency to increase. Thus formation and propagation of the mismatch dislocations takes place preferably in the softer buffer layers below the surface. This is not fulfilled in the case of most current buffer structures according to the state of the art. In these cases, the crystal lattice preferably relaxes in the soft layers at the surface and penetrating dislocations which grow further with the crystal are formed.

It was the object of the present invention to minimise the density of penetrating dislocations.

The object is achieved by the semiconductor component according to claim 1 and the uses of the semiconductor component according to claim 17.

According to the invention, a semiconductor component having a rear-side substrate and at least one front-side semiconductor layer and also a buffer disposed between substrate and the at least one front-side semiconductor layer is provided:
a) in each region (A, B, C, D, . . . ), the buffer layers being constructed from compound semiconductors which differ in composition,
b) the lattice constant in regions (A, B, C, D, . . . ) increasing or decreasing in growth direction,
c) the crystal lattices in regions (A, B, C, D . . . ) respectively being relaxed at least partially and
d) upon changing into another region (A, B, C, D . . . ), the crystal hardness of the adjacent buffer layers increasing in growth direction because of compound semiconductors which differ in composition.

The solution to the object is hence based on a novel buffer structure in which the relaxation of the crystal lattice is effected preferably by the formation of mismatch dislocations which are propagated below the surface in the plane up to the edge of the substrates.

The semiconductor component according to the invention has lower penetrating dislocation densities in metamorphic buffer layers. This applies in particular for buffer layers with increasing lattice constant. For example in the case where the semiconductor component concerns a solar cell, the efficiency is consequently significantly improved.

An advantageous feature of the present invention is that the buffer layer in the region of the gradient in the lattice constant consists of two or more layers of compound semiconductors of a different composition, which are selected such that the hardness increases in the course of the buffer or at least decreases as little as possible.

In order to avoid a decrease in hardness during the buffer growth, the material can be changed, i.e. elements are exchanged, added or removed with respect to the starting material. A selection of suitable materials is revealed from the hardness values for III-V compound semiconductors known from the state of the art. At least one buffer layer in region A of the buffer can therefore consist of a compound semiconductor being different from the buffer layers of the further regions B, C, D, . . . of the buffer.

Preferably, the compound semiconductors of the adjacent buffer layers differ by at least one element of the periodic table from the group consisting of elements of the compound semiconductors, preferably elements of group III and/or IV and/or V of the periodic table, being exchanged, added or removed.

Preferably, the compound semiconductors of the respective buffer layers of adjacent regions (A, B, C, D, . . . ) have different contents of an element of group III, in particular aluminium, in order to set different crystal hardness degrees. Thus, region B can have for example a lower Al content than region A, from which a higher crystal hardness degree results. Likewise, there should be understood, according to the invention, by different Al contents, that region B is free of aluminium.

A further preferred variant provides that, in the compound semiconductors of the respective buffer layers of the adjacent regions, at least one element of group V is replaced at least partially by a different element of group V. Thus, it is possible that the buffer layers in region A have arsenic as group V element, whilst the buffer layers in region B have phosphorus or antimony as group V element. However, it is likewise possible that the arsenic is replaced only partially by phosphorus or antimony. Equally, also a reverse exchange of arsenic or antimony to phosphorus can be effected. The crystal hardness degree in region B can also be increased by this measure.

Furthermore, it is preferred that, in growth direction, the buffer layer of the higher region, e.g. region B, has a 1-40% higher, preferably a 2-25% higher, particularly preferred 3-10% higher, crystal hardness degree than the buffer layer of the lower region, e.g. region A.

The lattice constant of the front-side semiconductor layer can be at least 1% higher or lower than the lattice constant of the substrate.

The respective regions (A, B, C, D, . . . ) preferably comprise at least two buffer layers. In particular, two or more buffer layers in region A consist of a different compound semiconductor from two or more buffer layers from region B.

The gradient of the lattice constant within regions (A, B, C, D, . . . ) respectively can be at least 0.5%.

Furthermore, the lattice constant of all the buffer layers in regions (A, B, C, D, . . . ) may increase or decrease in a monotone manner in growth direction.

In general, at least one buffer layer in the respective regions (A, B, C, D, . . . ) can consist of III-V compound semiconductors and can be doped with Si, Te, Zn, Se, Sb and/or C.

In particular, the crystal lattice in the respective regions (A, B, C, D, . . . ) is relaxed at a growth temperature (of 550 to 750° C.) at least up to 30%, in particular at least up to 80%, relative to the cubic lattice constant of the compound semiconductors which are used.

The semiconductor component according to the invention can be characterised in that
a) the substrate consists of Si, Ge, GaAs, GaP, InP and/or GaSb;
b) the first compound semiconductor consists of SiGe, AlGaInAs, GaInAs, GaAsP, GaAsSb, AlGaInAsSb, AIGaInP and/or GaInP;
c) the second compound semiconductor consists of SiGe, AlGaInAs, GaInAs, GaAsP, GaAsSb, AlGaInAsSb, AIGaInP and/or GaInP; and/or
d) the front-side semiconductor layer consists of Si, Ge, SiGe, GaAs, AlGaInAs, GaInAs, GaAsP, GaAsSb, AlGaInAsSb, InP, AIGaInP and/or GaInP.

A particularly preferred embodiment has a substrate made of Si or GaP, region A made of GaAsP and region B made of GaInP. Here, the lattice constant is converted to larger lattice constants.

A further particularly preferred embodiment provides a substrate made of GaAs or Ge, a region made of AlGaInAs and a region B made of AlGaInAs (with a lower Al content than in region A) or made of AlGaInP or GaInP. Here, the lattice constant is converted into larger lattice constants.

Preferably, the semiconductor component has, between the buffer and the at least one front-side semiconductor layer, at least one excess layer made of compound semiconductor which relaxes the crystal lattice relative to the at least one front-side semiconductor layer up to 90 to 100%.

The buffer of the semiconductor component can have a thickness in the range of 200 nm to 5,000 nm, in particular of 1,000 nm to 3,000 nm. The regions (A, B, C, D, . . . ) can have a thickness of respectively 100 nm to 2,500 nm, preferably of respectively 200 nm to 1,500 nm.

The semiconductor component can concern, according to the invention, a multiple solar cell.

The semiconductor component according to the invention or the multiple solar cell according to the invention can be used for current generation in satellites in space or in terrestrial photovoltaic concentrator systems.

The subject according to the invention is intended to be explained in more detail with reference to the subsequent Figures and examples without wishing to restrict said subject to the specific embodiments illustrated here.

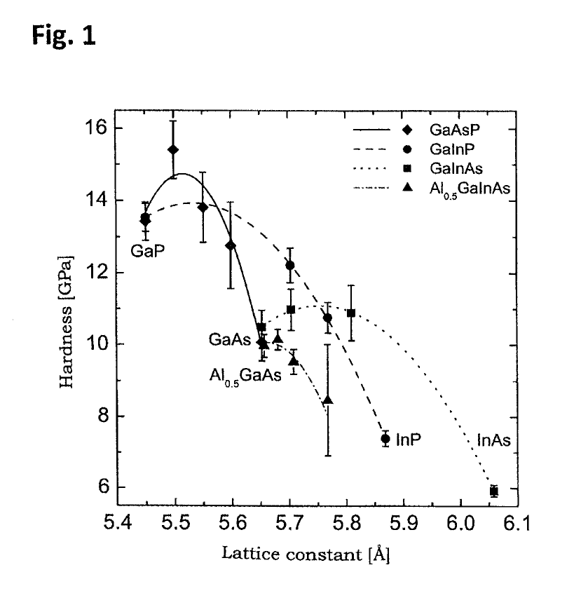

FIG. 1 shows the crystal hardness of various III-V materials as a function of their specific lattice constant.

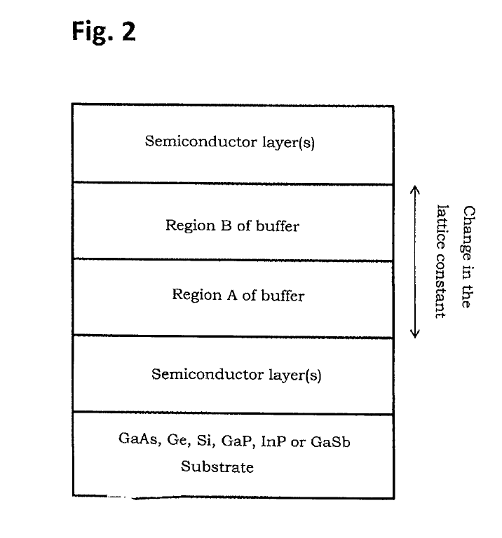

FIG. 2 shows schematically the structure of a semiconductor system according to the invention with a buffer made of two different regions (region A and region B). The average hardness in region B of the buffer thereby exceeds the average hardness in region A of the buffer.

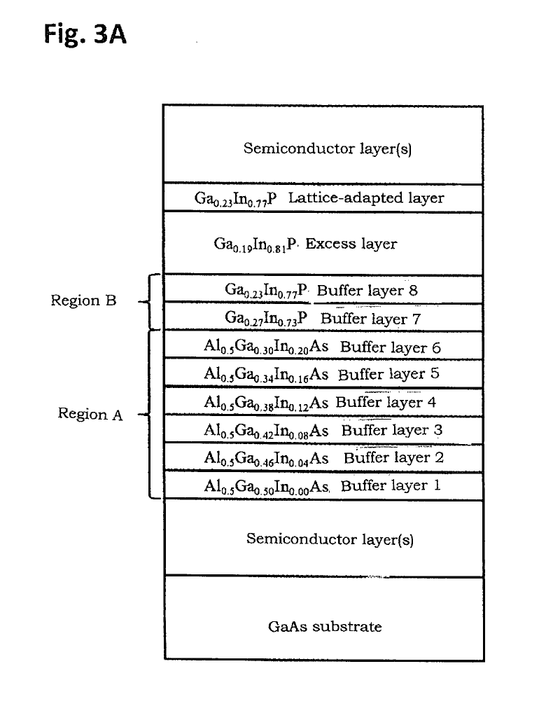

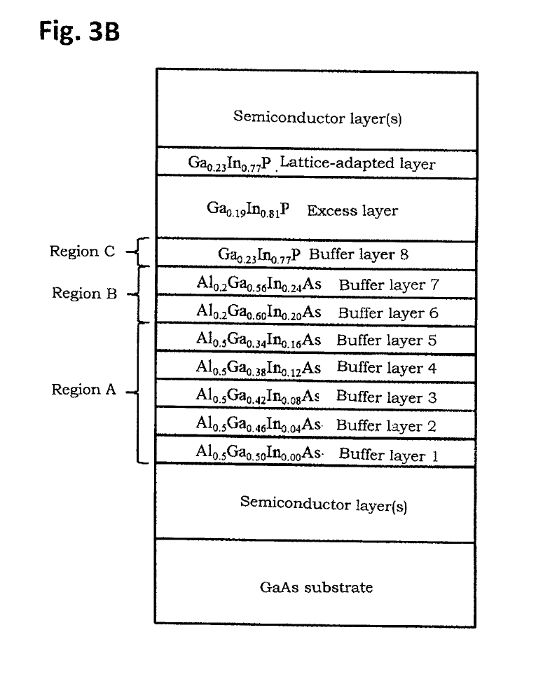

FIG. 3A shows schematically the structure of a semiconductor component according to the invention comprising a buffer which is constructed from six AlGaInAs layers (region A) and two GaInP layers (region B). In total, the buffer hence comprises eight buffer layers.

FIG. 3B shows schematically the structure of a semiconductor component according to the invention comprising a buffer which consists of five AlGaInAs layers (region A), two AlGaInAs layers (region B) and one GaInP layer (region C). In total, the buffer here also comprises eight buffer layers.

### EXAMPLE 1

### Semiconductor Component Having Two Different Buffer Regions

The semiconductor component according to the invention has a hardness buffer, this buffer converting the lattice constant of the substrate, continuously or incrementally, to the lattice constant of the front-side semiconductor layer. According to the invention, the buffer hereby has, in growth direction of the semiconductor component, firstly a region A having at least one buffer layer made of a compound semiconductor, and also a region B having at least one buffer layer made of a second compound semiconductor (see FIG. 2).

According to the invention, the average crystal hardness degree of region B is greater than the average crystal hardness degree of region A and regions A and B are at least partially relaxed.

### EXAMPLE 2

### Semiconductor Component Having Eight Buffer Layers

In the case of a transition of gallium arsenide to larger lattice constants, the gradient layer begins firstly in the softer material made of AlGaInAs and then changes, with greater lattice constants, to GaInAs, AIGaInP or GaInP (see FIG. 3a). The buffer consists of six AlGaInAs layers (=region A) and two GaInP layers (=region B), the crystal hardness of the layers in region B on average being higher than the crystal hardness in region A.

In total, the buffer comprises eight buffer layers which all have a different lattice constant which increases from the substrate in the direction of the Ga_{0.23}In_{0.77}P layer which is lattice-adapted to the semiconductor layer (i.e. in growth direction). In addition, this semiconductor component comprises, on the eighth buffer layer, an excess layer made of Ga_{0.19}In_{0.81}P which leads to the layers 1 to 8 situated thereunder relaxing further. On the excess layer, a layer made of Ga_{0.23}In_{0.77}P which is lattice-adapted to the semiconductor layer is situated. Following the lattice-adapted layer made of GaInP there is the semiconductor structure. One possible application for this further buffer structure is an inverted metamorphic triple solar cell with active p-n junctions in the materials GaInP (1.9 eV), GaAs (1.4 eV) and GaInAs (1.0 eV), the buffer structure being incorporated between the partial solar cell made of GaAs and GaInAs.

### EXAMPLE 3

### Semiconductor Component Having Eight Buffer Layers

As in example 2, in example 3 also a transition of gallium arsenide to a greater lattice constant by means of eight buffer layers is achieved (see FIG. 3B). The buffer layer is divided into three regions A (five AlGaInAs layers), B (two AlGaInAs layers with a lower Al content than in region A) and C (a layer made of GaInP), respectively an increase in the crystal hardness being achieved by the transition from region A to B and from region B to C.

In total, the buffer comprises eight buffer layers which all have a different lattice constant which increases from the substrate in the direction of the Ga_{0.23}In_{0.77}P layer which is lattice-adapted to the semiconductor layer (i.e. in growth direction). In addition, this semiconductor component comprises, on the eighth buffer layer, an excess layer made of Ga_{0.19}In_{0.81}P which leads to the layers situated thereunder relaxing further. On the excess layer, a layer made of Ga_{0.23}In_{0.77}P which is lattice-adapted to the semiconductor layer is situated. Following the lattice-adapted layer made of GaInP there is the semiconductor structure. A possible application for this buffer structure is an inverted metamorphic triple solar cell with active p-n junctions in the materials GaInP (1.9 eV), GaAs (1.4 eV) and GaInAs (1.0 eV), the buffer structure being incorporated between the partial solar cell made of GaAs and GaInAs.

In the case of a transition of gallium phosphide to greater lattice constants, a gradient layer begins preferably firstly in GaAsP (region A) and then changes, at greater lattice constants, to GaInP (region B).

In the case of a transition of gallium arsenide to greater lattice constants, a gradient layer begins preferably firstly in AlGaInAs (region A) and then changes to a lower Al content (region B). Furthermore, transitions from AlGaInAs to GaInAs, from AlGaInAs to AIGaInP, from AIGaInP to GaInP, from GaInAs to GaInP or from GaInAs to AIGaInP are useful. By changing the compound semiconductor, respectively an increase in hardness is achieved (see in this respect also FIG. 1).

1. A semiconductor component having a rear-side substrate and at least one front-side semiconductor layer and also a buffer disposed between substrate and the at least one front-side semiconductor layer, the buffer converting a lattice constant of the substrate, continuously or incrementally, to a lattice constant of the front-side semiconductor layer, the buffer, in growth direction of the semiconductor component, having a plurality of regions (A, B, C, D, . . . ) with respectively at least one buffer layer and
a) in each region (A, B, C, D, . . . ), the buffer layers being constructed from compound semiconductors which differ in composition,
b) the lattice constant in regions (A, B, C, D, . . . ) increasing or decreasing in growth direction,
c) the crystal lattices in regions (A, B, C, D . . . ) respectively being relaxed at least partially and
d) upon changing into another region (A, B, C, D . . . ), the crystal hardness of the adjacent buffer layers increasing in growth direction because of compound semiconductors which differ in composition.

2. A semiconductor component having a rear-side substrate and at least one front-side semiconductor layer and also a buffer disposed between substrate and the at least one front-side semiconductor layer, the buffer converting a lattice constant of the substrate, continuously or incrementally, to a lattice constant of the front-side semiconductor layer, the buffer, in growth direction of the semiconductor component, having a plurality of regions (A, B, C, D, . . . ) with respectively at least one buffer layer and
a) in each region (A, B, C, D, . . . ), the buffer layers being constructed from compound semiconductors which differ in composition,
b) the lattice constant in regions (A, B, C, D, . . . ) increasing or decreasing in growth direction,
c) the crystal lattices in regions (A, B, C, D . . . ) respectively being relaxed at least partially and
d) upon changing into another region (A, B, C, D . . . ), the crystal hardness of the adjacent buffer layers increasing in growth direction because of compound semiconductors which differ in composition,
wherein the at least one buffer layer in a region (A) of the buffer consists of a compound semiconductor being different from a compound semiconductor of the at least one buffer layer of further regions (B, C, D, . . . ) of the buffer, wherein the compound semiconductors are different because elements are exchanged, added or removed.

3. A semiconductor component according to claim 1 or 2, wherein the compound semiconductors of the adjacent buffer layers differ by at least one element of the periodic table from the group consisting of elements of the compound semiconductors, preferably elements of group III and/or IV and/or V of the periodic table, being exchanged, added or removed.

4. A semiconductor component according to claim 1 or 2, wherein the compound semiconductors of the respective buffer layers of the adjacent regions (A, B, C, D, . . . ) have different contents of an element of group III, in particular aluminium, in order to set different crystal hardness degrees.

5. A semiconductor component according to claim 1 or 2, wherein the compound semiconductors of the respective buffer layers of the adjacent regions, at least one element of group V is replaced at least partially by a different element of group V in order to set different crystal hardness degrees.

6. A semiconductor component according to claim 1 or 2, wherein growth direction, the buffer layer of the higher region, e.g. region B, has a 1-40% higher, preferably 3-10% higher, crystal hardness degree than the buffer layer of the lower region, e.g. region A.

7. A semiconductor component according to claim 1 or 2, wherein the lattice constant of the front-side semiconductor layer is at least 1% higher or lower than the lattice constant of the substrate.

8. A semiconductor component according to claim 1 or 2, wherein the respective regions (A, B, C, D, . . . ) comprise at least two buffer layers.

9. A semiconductor component according to claim 8, wherein the gradient of the lattice constant within regions (A, B, C, D, . . . ) respectively is at least 0.5%.

10. A semiconductor component according to claim 1 or 2, wherein the lattice constant of all the buffer layers in regions (A, B, C, D, . . . ) increases or decreases in a monotone manner in growth direction.

11. A semiconductor component according to claim 1 or 2, wherein at least one buffer layer in regions (A, B, C, D, . . . ) consists of III-V compound semiconductors and is doped with Si, Sb, Te, Zn, Se and/or C.

12. A semiconductor component according to claim 1 or 2, wherein the crystal lattice in the respective regions (A, B, C, D, . . . ) is relaxed, at a growth temperature, at least up to 30%, in particular at least up to 80%, relative to the cubic lattice constant of the compound semiconductors which are used.

13. A semiconductor component according to claim 1 or 2, wherein
a) the substrate consists of Si, Ge, GaAs, GaP, InP and/or GaSb;
b) the compound semiconductor consists of SiGe, AlGaInAs, GaInAs, GaAsP, GaAsSb, AlGaInAsSb, AlGaInP and/or GaInP;
c) the different compound semiconductor consists of SiGe, AlGaInAs, GaInAs, GaAsP, GaAsSb, AlGaInAsSb, AIGaInP and/or GaInP; and/or
d) the front-side semiconductor layer consists of Si, Ge, SiGe, GaAs, AlGaInAs, GaInAs, GaAsP, GaAsSb, AlGaInAsSb, InP, AlGaInP and/or GaInP.

14. A semiconductor component according to claim 1 or 2, wherein the semiconductor component has, between the buffer and the at least one front-side semiconductor layer, at least one excess layer made of compound semiconductor which relaxes the crystal lattice relative to the at least one front-side semiconductor layer to 90 to 100%.

15. A semiconductor component according to claim 1 or 2, wherein the buffer has a thickness in the range of 200 nm to 5,000 nm, in particular of 1,000 to 3,000 nm.

16. A semiconductor component according to claim 1 or 2, wherein the regions (A, B, C, D, . . . ) have a thickness of respectively 100 nm to 2,500 nm, in particular of respectively 200 nm to 1,500 nm.

17. A semiconductor component according to claim 1 or 2, wherein the semiconductor component is a multiple solar cell.

18. Use of the semiconductor component according to claim 1 or 2 for current generation in satellites in space or in terrestrial photovoltaic concentrator systems.
